(19) United States
(12) Patent Application Publication
(10) Pub. No.: US 2015/0185792 A1
(43) Pub. Date: Jul. 2, 2015

(54) DUAL-layer SYSTEM COMPUTER ENCLOSURE

(71) Applicant: Shih-Wun Li, Taoyuan County (TW)

(72) Inventor: Shih-Wun Li, Taoyuan County (TW)

(21) Appl. No.: 14/140,538

(22) Filed: Dec. 26, 2013

(51) Int. Cl. G06F 1/20; H05K 7/20; G06F 1/18

(52) U.S. Cl. CPC G06F 1/20; G06F 1/181; H05K 7/20136

(57) ABSTRACT

The present invention provides a dual-layer system computer enclosure, which comprises: an upper case member installed above the lower case member, at least one side of which is formed with an opening which is connected with a moveable side cover through a connection device, the rear is formed with a through hole on which a rear cover is installed; at least a ventilation cover correspondingly installed in a concave seat of the ventilation cover. With the present invention, the lower case member and the upper case member are allowed to work together to form a single-layer or dual-layer structures for expansion, and the rear cover installed at the rear of the upper case member can allow the operation of hardware replacement, the blades can adjust the amount of ventilation air flow.

### SUMMARY OF THE INVENTION

One primary object of the present invention is to provide a dual-layer system computer enclosure having an improved structure for overcoming the problems of conventional arts.

The problem to be solved by the present invention is that a conventional computer structure is mainly a fixed type, and restrained by its enclosure so large scale expansion is not able to be processed. In exchange of a computer enclosure with larger expansion space, the original computer has to be thrown away which may cause wastes of resources and especially the operations such as backup files, transferring files, and computer setting are time consuming. In addition, a conventional computer utilizes a small fan installed at the rear of the enclosure for heat dissipation and ventilation, and ever smaller holes formed on the front or side panels for discharging and ventilating airs, the mentioned structure has very limited or even poor air convection and ventilation, not to mention heat dissipation, thereby occurrences of temperature raising, component damaging and overheat crash being inevitable. If the hardware is desired to be expanded or replaced, the detach/attach operation cannot be directly performed from the outside, so the enclosure of the computer has to be detached for performing operation, examination, maintenance and expansion in a very small space inside the enclosure. In addition, the conventional computer mostly has single system, so some software may not be run after upgrading or changing versions.

For achieving the mentioned object, the present invention provides a dual-layer system computer enclosure, which comprises:
a lower case member, having a central through hole at the center, and the top periphery is formed with plural top fastening holes;
an upper case member, installed above the lower case member, and having a central through hole at the center, the bottom is formed with a mount flange having plural through holes and allowing a fasten unit to pass through for being fastened with the lower case member, the rear is formed with a through hole on which a rear cover allowing hardware to be changed is installed, and the top periphery of the upper case member is formed with corresponding top fastening holes;
a ventilation cover, installed on the upper case member, the center thereof has a concave seat having one side installed with at least a set of a shaft hole and an elongated slide hole and the other end installed with corresponding shaft holes, the bottom is installed with a slide rail having inclined slots provided at the side corresponding to the elongated hole, and the top of the slide rail is installed with a push button corresponding to a concave hole formed on the ventilation cover, and the bottom of the slide rail is installed with positioning slots positioned by a fasten unit, and at least two convex pieces are installed at corresponding locations at the bottom outer edge of the ventilation cover, each convex piece has a fastening hole corresponding to the top fastening holes of the upper case members;
at least a blade, having side ends installed with rotation shafts and slide shafts, the rotation shafts are corresponding to the shaft holes at two sides of the concave seat of the ventilation cover, and the slide shafts are corresponding to the elongated holes at two sides of the concave seat and the inclined slots formed at one side of the slide rail.

Preferably, the upper case member is a computer mainframe.

Preferably, the lower case member is another computer mainframe.

Moreover, at least one side of the upper case member is formed with an opening connected with a moveable side cover through a connection device.

Preferably, hardware to be replaced at the rear cover is selected from a group consisted of a fan and a power supply unit (PSU), or a combination thereof.

Preferably, the slide rail of the ventilation cover is in an L-shape.

Preferably, the blade is in an L-shape.

Moreover, the blade is further formed with ventilation holes.

For achieving the mentioned object, the present invention provides a dual-layer system computer enclosure, which comprises:
a lower case member, having a central through hole at the center, and the top periery is formed with plural top fastening holes;
a ventilation cover, installed on the lower case member, the center thereof has a concave seat having one side installed with at least a set of a shaft hole and an elongated slide hole and the other end installed with corresponding shaft holes, the bottom is installed with a slide rail having inclined slots provided at the side corresponding to the elongated hole, and the top of the slide rail is installed with a push button corresponding to a concave hole formed on the ventilation cover, and the bottom of the slide rail is installed with positioning slots positioned by a fasten unit, and at least two convex pieces are installed at corresponding locations at the bottom outer edge of the ventilation cover, each convex piece has a fastening hole corresponding to the top fastening holes of the lower case members;
at least a blade, having side ends installed with rotation shafts and slide shafts, the rotation shafts are corresponding to the shaft holes at two sides of the concave seat of the ventilation cover, and the slide shafts are corresponding to the elongated holes at two sides of the concave seat and the inclined slots formed at one side of the slide rail.

Moreover, the blade is further formed with ventilation holes.

Preferably, the lower case member is another computer mainframe.

Preferably, the slide rail of the ventilation cover is in an L-shape.

Preferably, the blade is in an L-shape.

With the design provided by the present invention, the lower case member and the upper case member are allowed to work together to form a single-layer or dual-layer structures for expansion, and the rear cover installed at the rear of the upper case member can be detached/attached from outside for allowing the operation of hardware replacement, and with the rotation operation processed to the blades of the ventilation cover installed on the top ends of the upper case member being installed on the lower case member or the upper case member, the amount of ventilation air flow can be adjusted.

### BRIEF DESCRIPTION OF THE DRAWINGS

FIG. 1 is a perspective exploded view of the present invention;

FIG. 1a is a perspective exploded view of the present invention being viewed from another angle;

FIG. 2 is a perspective view showing the assembly of the present invention;

FIG. 3 is a cross sectional view showing the assembly of the present invention;

FIG. 4 is a perspective view showing the assembly in which the moveable side cover being in an engaged state according to the present invention; and

FIG. 5 is a perspective view showing the assembly in which the lower case member being installed with the ventilation cover while the upper case member not being provided, according to the present invention.

### DESCRIPTION OF MAIN COMPONENT SYMBOLS

1: ventilation cover

10: concave hole

11: concave seat

110: shaft hole

111: elongated slide hole

112: shaft hole

12: slide rail

121: inclined slot

122: positioning slot

123: fasten unit

124: push button

13: convex piece

131: fastening hole

2: blade

21: ventilation hole

22: rotation shaft

23: slide shaft

3: lower case member

30: central through hole

31: top fastening hole

32: fasten unit

4: upper case member

400: central through hole

40: mount flange

401: fastening hole

41: through hole

411: fastening hole

42: rear cover

421: fastening hole

422: top fastening hole

43: fasten unit

44: fasten unit

47: opening

45: connection device

46: moveable side cover

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention

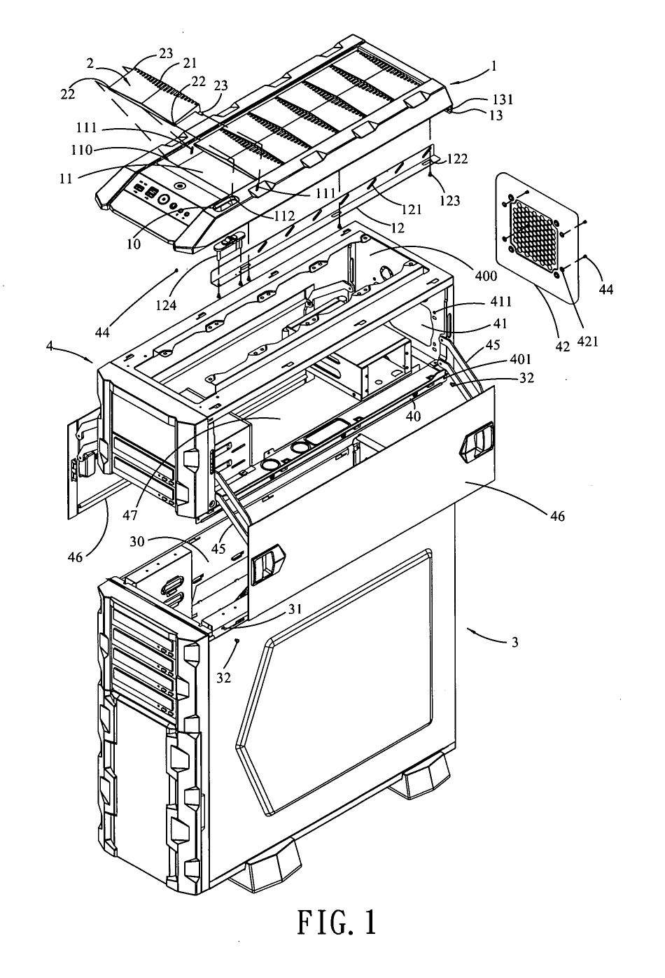

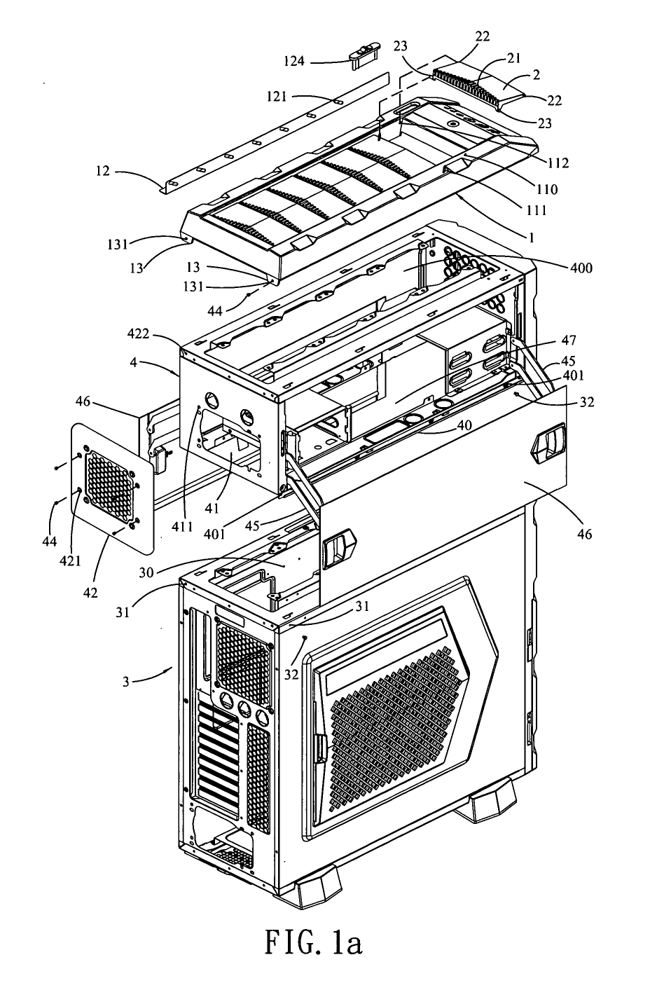

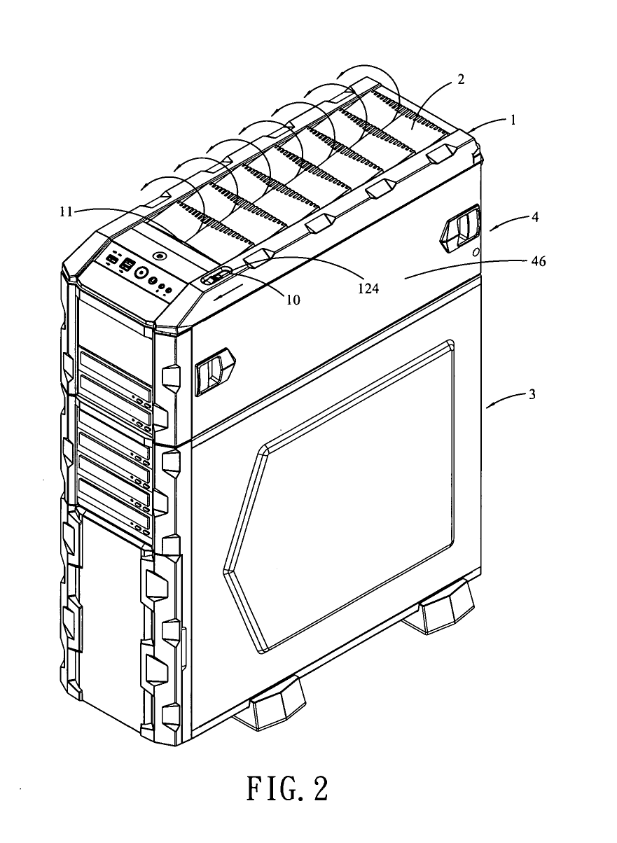

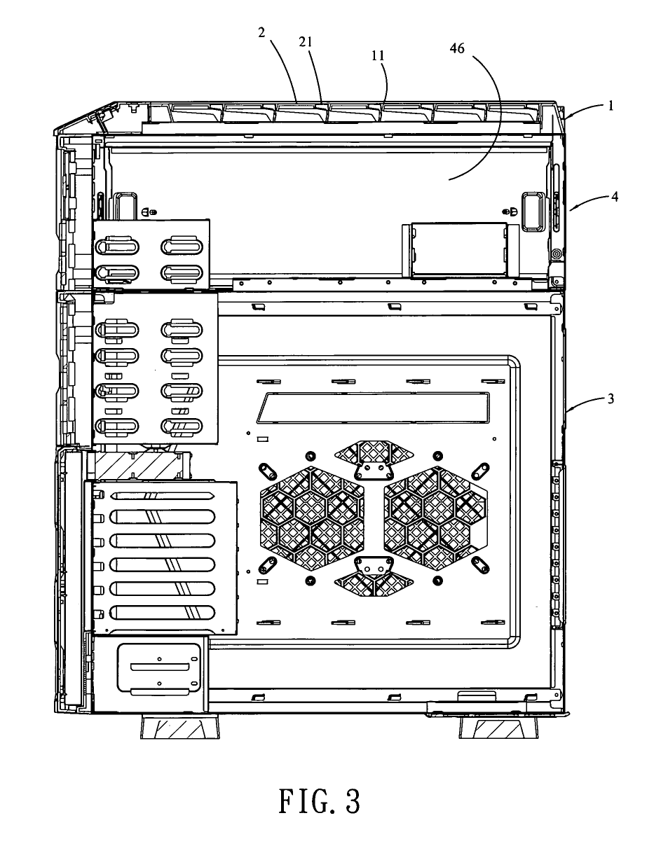

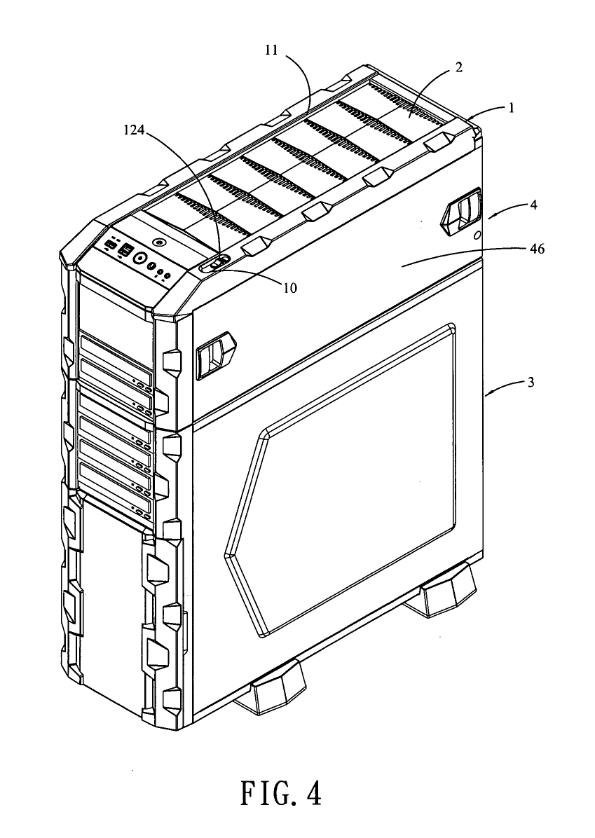

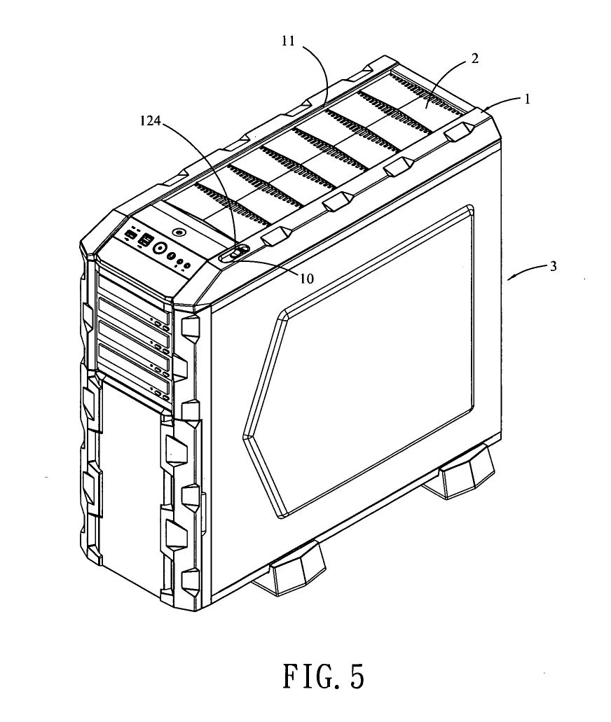

Please refer to FIG. 1, FIG. 1a, FIG. 2, FIG. 3, FIG. 4 and FIG. 5, wherein FIG. 1 is a perspective exploded view of the present invention, FIG. 1a is a perspective exploded view of the present invention being viewed from another angle, FIG. 2 is a perspective view showing the assembly of the present invention, FIG. 3 is a cross sectional view showing the assembly of the present invention, FIG. 4 is a perspective view showing the assembly in which the moveable side cover being in an engaged state according to the present invention and FIG. 5 is a perspective view showing the assembly in which the lower case member being installed with the ventilation cover while the upper case member not being provided, according to the present invention.

According to one preferred embodiment of the present invention, the dual-layer system computer enclosure comprises a lower case member 3, an upper case member 4, a ventilation cover 1, and at least a blade 2.

According to this embodiment, a computer mainframe is adopted as the lower case member 3 for the purpose of illustration and fully disclosure and shall not be a limitation of the scope of the present invention; in actual use, various electronic products can be adopted. The center of the lower case member 3 is formed with a central through hole 30 allowing air to flow, and the top peripheral thereof is formed with plural fastening holes 31 for providing a fastening function.

According to this embodiment, another computer mainframe is adopted as the upper case member 4 for the purpose of illustration and fully disclosure and shall not be a limitation of the scope of the present invention; in actual use, various electronic products can be adopted. The upper case member 4 is optionally installed on the lower case member 3, and the center is also formed with a central through hole 400 allowing air to flow, the bottom thereof is installed with a mount flange 40 capable of being sleeved with the lower case member 3. In order to enable the mount flange 40 to be fastened with the lower case member 3 through a fasten unit 32, the mount flange 40 is formed with plural fastening holes 401; in order to provide convenience for the operations of maintenance, expansion and examination, the upper case member 4 is formed with at least an opening 47, and a moveable side cover 46 is connected through a connection device 45; in order to allow hardware to be attached/detached or modified from the outside, a through hole 41 is formed at the rear, wherein the lateral sides thereof have plural fastening holes 411 for the purpose of fastening; in order to provide a protection and false contact prevention to the hardware for the hardware replacement, e.g. but not limited to a fan or power supply unit (PSU), a rear cover 42 is installed on the through hole 41 and formed with fastening holes 421 corresponding to the fastening holes 411, and a fasten unit 44 is provided for connecting the two fastening holes as one piece, meanwhile the top periphery of the upper case member 4 is formed with corresponding top fastening holes 422.

The ventilation cover 1 is optionally installed on the lower case member 3 (as shown in FIG. 5) or on the upper case member 4 installed above the lower case member 3 (as shown in FIG. 2), the center of the ventilation cover 1 is installed with a concave seat 11 having a set of a shaft hole 110 and an elongated slide hole 111 at one side, and the other side of the concave seat 11 is formed with a corresponding shaft hole 12, the bottom thereof is installed with a slide rail 12. In this embodiment, the slide rail 12 is in an L-shape, said arrangement is provided for illustration and shall not be a limitation of the scope of the present invention, various shapes suitable for proving substantially the same function can be adopted. The slide rail 12 is installed with inclined slots 121 at the side corresponding to the elongated slide hole 111, and a push button 124 is installed thereon corresponding to a concave hole 10 formed on the ventilation cover 1, the bottom of the slide rail 12 is installed with positioning slots 122 positioned by fasten units 123, for allowing the ventilation cover 1 to be fastened on the upper case member 4 or the lower case member 3, the bottom outer edges are installed with at least two convex pieces 13 at corresponding locations, and each convex piece 13 is formed with a fastening hole 131 corresponding to the fastening holes 422, 31 of the upper and the lower case members 4, 3, and the fasten unit 44 is served to connect and fasten the above mentioned components.

In this embodiment, the at least one blade 2 is in an L-shape, which is an example for full disclosure of the present invention, in actual use the blade 2 can be formed in various suitable shapes which are within the scope of the present invention, distal ends of the blade 2 are respectively installed with a rotation shaft 22 and a slide shaft 23, wherein the rotation shafts 22 are corresponding to the shaft holes 110, 112 at two sides of the concave seat 11 of the ventilation cover 1, and the slide shafts 23 are corresponding to the elongated slide holes 111 at two sides of the concave seat 11 and the inclined slots 121 formed at one side of the slide rail 12, the blade 2 is further formed with ventilation holes 21.

The top end of the lower case member 3 can be easily installed with the upper case member 4 through the mount flange 40, and the fasten unit 32 passes through the fastening holes 401 at the mount flange 40 of the upper case member 4 and the top fastening holes 31 correspondingly formed at the top end of the lower case member 3 for the purpose of connecting and fastening. The ventilation cover 1 is fastened through the convex pieces 13 having fastening holes 131 and symmetrically arranged at the bottom periphery being fastened with the corresponding top fastening holes 422, 31 of the upper case member 4 or the lower case member 3. Moreover, a through hole 41 is formed at the rear of the upper case member 4, and a rear cover 42 is installed thereon for allowing the operation of changing hardware to be performed from the exterior of the upper case member 4, thus the object of changing hardware can be achieved without detaching the upper case member 4. In addition, according to the present invention, the ventilation cover 1 installed on the upper case member 4 or the lower case member 3 has a concave seat 11 installed with at least a blade 2 at the center, so with a push action performed by the push button 124 protrudingly installed in the concave hole 10 of the ventilation cover 1, the slide rail 12 having the inclined slots 121 is displaced, so the end of the blade 2 having the slide shafts 23 being installed in the inclined slots 121 and the elongated slide hole 111 can be lifted or engaged for adjustment through the other end of the blade 2 with the rotation shafts 22 installed in the shaft holes 110, 112 being served as the shaft center, thus an object of heat dissipation or air ventilation can be achieved by communicating with the central through holes 400, 30 of the upper case member 4 and the lower case member 3. Moreover, at least one side of the upper case member 4 is formed with an opening 47, and connected with a moveable side cover 46 through a connection device 45, therefore the interior of the upper case member 4 can be directly opened (as shown in FIG. 2) or engaged (as shown in FIG. 4) through the moveable side cover 46.

With the design provided by the present invention, the lower case member 3 and the upper case member 4 are allowed to work together to form a single-layer or dual-layer structures for expansion, so the problem of software not being able to run due to upgrade or version change is avoided, and the rear cover 42 installed at the rear of the upper case member 4 can be detached/attached from outside for allowing the operation of hardware replacement, and with the rotation operation processed to the blades of the ventilation cover installed on the top end of the upper case member being installed on the lower case member 3 or on the upper case member 4, the amount of ventilation air flow can be adjusted, and with the opening/engaging of the moveable side cover 46, operation, expansion, maintenance and examination can be directly performed, thereby increasing the convenience in use and simplifying the operation.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific examples of the embodiments disclosed and that modifications and other embodiments are intended to be included within the scope of the appended claims. Although specific terms are employed herein, they are used in a generic and descriptive sense only and not for purposes of limitation.

What is claimed is:

1. a dual-layer system computer enclosure, comprising:
a lower case member, having a central through hole at the center, and the top periphery is formed with plural top fastening holes;
an upper case member, installed above the lower case member, and having a central through hole at the center, the bottom is formed with a mount flange having plural through holes and allowing a fasten unit to pass through for being fastened with the lower case member, the rear is formed with a through hole on which a rear cover allowing hardware to be changed is installed, and the top periphery of the upper case member is formed with corresponding top fastening holes;
a ventilation cover, installed on the upper case member, the center thereof has a concave seat having one side installed with at least a set of a shaft hole and an elongated slide hole and the other end installed with corresponding shaft holes, the bottom is installed with a slide rail having inclined slots provided at the side corresponding to the elongated hole, and the top of the slide rail is installed with a push button corresponding to a concave hole formed on the ventilation cover, and the bottom of the slide rail is installed with positioning slots positioned by a fasten unit, and at least two convex pieces are installed at corresponding locations at the bottom outer edge of the ventilation cover, each convex piece has a fastening hole corresponding to the top fastening holes of the upper case members;
at least a blade, having side ends installed with rotation shafts and slide shafts, the rotation shafts are corresponding to the shaft holes at two sides of the concave seat of the ventilation cover, and the slide shafts are corresponding to the elongated holes at two sides of the concave seat and the inclined slots formed at one side of the slide rail.

2. The dual-layer system computer enclosure according to claim 1, wherein at least one side of the upper case member is formed with an opening which is connected with a moveable side cover through a connection device.

3. The dual-layer system computer enclosure according to claim 1, wherein the blade is further formed with ventilation holes.

4. The dual-layer system computer enclosure according to claim 2, wherein the blade is further formed with ventilation holes.

5. The dual-layer system computer enclosure according to claim 3, wherein the upper case member is a computer mainframe.

6. The dual-layer system computer enclosure according to claim 4, wherein the upper case member is a computer mainframe.

7. The dual-layer system computer enclosure according to claim 5, wherein the lower case member is another computer mainframe.

8. The dual-layer system computer enclosure according to claim 6, wherein the lower case member is another computer mainframe.

9. The dual-layer system computer enclosure according to claim 7, wherein the hardware to be replaced at the rear cover is selected from a group consisted of a fan and a power supply unit (PSU), or a combination thereof.

10. The dual-layer system computer enclosure according to claim 8, wherein the hardware to be replaced at the rear cover is selected from a group consisted of a fan and a power supply unit (PSU), or a combination thereof.

11. The dual-layer system computer enclosure according to claim 9, wherein the slide rail of the ventilation cover is in an L-shape.

12. The dual-layer system computer enclosure according to claim 10, wherein the slide rail of the ventilation cover is in an L-shape.

13. The dual-layer system computer enclosure according to claim 11, wherein the blade is in an L-shape.

14. The dual-layer system computer enclosure according to claim 12, wherein the blade is in an L-shape.

15. A dual-layer system computer enclosure comprises:
a lower case member, having a central through hole at the center, and the top periphery is formed with plural top fastening holes;
a ventilation cover, installed above the lower case member, the center thereof has a concave seat having one side installed with at least a set of a shaft hole and an elongated slide hole and the other end installed with corresponding shaft holes, the bottom is installed with a slide rail having inclined slots provided at the side corresponding to the elongated hole, and the top of the slide rail is installed with a push button corresponding to a concave hole formed on the ventilation cover, and the bottom of the slide rail is installed with positioning slots positioned by a fasten unit, and at least two convex pieces are installed at corresponding locations at the bottom outer edge of the ventilation cover, each convex piece has a fastening hole corresponding to the top fastening holes of the lower_case members;
at least a blade, having side ends installed with rotation shafts and slide shafts, the rotation shafts are corresponding to the shaft holes at two sides of the concave seat of the ventilation cover, and the slide shafts are corresponding to the elongated holes at two sides of the concave seat and the inclined slots formed at one side of the slide rail.

16. The dual-layer system computer enclosure according to claim 15, wherein the blade is further formed with ventilation holes.

17. The dual-layer system computer enclosure according to claim 15, wherein the lower case member is a computer mainframe.

18. The dual-layer system computer enclosure according to claim 15, wherein the slide rail of the ventilation cover is in an L-shape.

19. The dual-layer system computer enclosure according to claim 15, wherein the blade is in an L-shape.
